(19) United States
(12) Patent Application Publication
(10) Pub. No.: US 2026/0282826 A1
(43) Pub. Date: Sep. 17, 2026

(54) ADAPTIVE SETTLING WINDOW FOR WAFER HANDLING ROBOT

(71) Applicant: ASM IP Holding B.V., Almere (NL)

(72) Inventors: Pradeep Nambiath, Mesa, AZ (US); Salam Harb, Scottsdale, AZ (US); Samer Banna, Phoenix, AZ (US); Ananthakrishnan Bhagyarajan, Tama-shi, Tokyo (JP)

(21) Appl. No.: 19/563,311

(22) Filed: Mar. 11, 2026

Related U.S. Application Data
(60) Provisional application No. 63/772,148, filed on Mar. 14, 2025.

(51) Int. Cl. H10P 72/50; H10P 72/00; H10P 72/30

(52) U.S. Cl. CPC H10P 72/53; H10P 72/0606; H10P 72/3302; H10P 72/3306; H10P 72/3311

(57) ABSTRACT

A method and system for adjusting a settling window in a substrate processing system uses Automatic Wafer Centering (AWC) sensor data. The method and system transfer a wafer through an AWC sensor array during place and pick operations, calculates wafer positions, and determines a position difference. The settling window is adjusted based on the calculated difference to minimize robot move times and increase throughput. The system may include a wafer transfer robot, AWC sensor array, processing chamber, and controller that performs the adjustment method. As the system is used over time, the settling window is automatically adjusted to account for component wear affecting robot performance. This approach enables active control of settling window accuracy based on user-defined wafer placement settings, providing an efficient and adaptive solution.

### CROSS-REFERENCE TO RELATED APPLICATIONS

This application claims priority to U.S. Provisional Patent Application Ser. No. 63/772,148 filed Mar. 14, 2025 and titled ADAPTIVE SETTLING WINDOW FOR WAFER HANDLING ROBOT, the disclosure of which is hereby incorporated by reference in its entirety.

### FIELD

The present disclosure relates generally to the field of semiconductor processing methods and systems and to the field of device and integrated circuit manufacture. More particularly the present disclosure generally relates to wafer-handling robots with improved positioning accuracy and efficiency.

### BACKGROUND

Substrate processing systems often employ wafer-handling robots to transfer wafers between various chambers and components. These robots utilize end effectors to grasp and move wafers with precision. When a wafer-handling robot changes the location, direction, or velocity of its end effector, it requires a certain amount of time to settle into the desired position and velocity. For instance, as a robot arm moves a wafer through a gate valve into a chamber and places it on a wafer support, the end effector decelerates to come to rest at the final position. However, depending on factors such as the robot arm's velocity, acceleration, inertia, stiffness, and actuator force, the position of the end effector may oscillate or vibrate before finally settling.

There is a need for an improved method to dynamically optimize operation, balancing accuracy and speed while adapting to real-time conditions and wafer characteristics. The solution should use advanced sensing to monitor wafer positions during pick and place operations, enabling automatic adjustments without frequent manual interventions or downtime.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various aspects of the present disclosure relate to providing a system and method that utilizes Automatic Wafer Centering (AWC) sensor data to calculate and adjust settling windows in substrate processing systems, thereby optimizing wafer handling operations. Additional aspects of the present disclosure relate to a method for automatically adjusting settling windows based on changes in wafer-handling robot performance due to component wear over time, enhancing system adaptability and longevity. Still further aspects of the present disclosure relate to enabling a wafer-handling robot to actively control the accuracy of the settling window based on user-defined wafer placement accuracy settings, improving precision and flexibility in semiconductor manufacturing processes.

In accordance with examples of the disclosure, a method for adjusting a settling window in a substrate processing system is provided. The method may involve transferring a wafer through a field of view of an Automatic Wafer Centering sensor array (or AWC sensor array) using a current settling window during a place operation. A first wafer position on an end effector may be calculated during the place operation using the AWC sensor array. The wafer is then transferred through the field of view of the AWC array using the current settling window during a pick operation. A second wafer position on the end effector may be calculated during the pick operation using the AWC sensor array. The method may further include calculating a position difference between the first wafer position and the second wafer position, and adjusting the settling window based on the calculated position difference. The method further may further comprise comparing the calculated position difference to a predetermined position difference value. If the calculated position difference is less than or equal to the predetermined position difference value, a new settling window is written to system memory. The adjustment of the settling window may involve decreasing a settling time in response to the calculated position difference being less than a lower threshold, or increasing the settling time in response to the calculated position difference being greater than an upper threshold. The method may also include repeating the transferring, calculating, and adjusting steps for multiple wafers, and determining a trend in settling time adjustments over time. This allows for continuous optimization of the wafer handling process. The AWC sensor array used in the method may comprise at least two sensors positioned on opposite sides of a gate valve, enabling accurate wafer position detection during transfer operations. The method further may involve storing the calculated position difference in memory and using the stored position difference to adjust subsequent wafer handling operations, enhancing the system's adaptive capabilities. Calculating the wafer position during the place or pick operation may involve detecting an edge of the wafer using the AWC sensor array and determining an offset of the wafer center from a predetermined position on the end effector. The adjustment of the settling window may also include adjusting a velocity profile of the end effector, allowing for fine-tuned control of wafer movement.

In accordance with examples of the disclosure, a substrate processing system is provided. The system may comprise a wafer transfer robot with an end effector, an AWC sensor array, a processing chamber with a substrate support, and a controller. The controller may control the wafer transfer robot to transfer a wafer during place and pick operations through a field of view of the AWC sensor array using a current settling window. The controller may calculate wafer positions on the end effector during both operations using the AWC sensor array, calculate a position difference between the wafer positions, and adjust the settling time based on the calculated position difference. The system may include a memory coupled to the controller. The controller may compare the calculated position difference to a predetermined position difference value, determine if the calculated position difference is less than or equal to the predetermined position difference value, and write a new settling window to the memory based on this determination. The controller in the system adjusts the settling window by decreasing or increasing the settling time based on whether the calculated position difference is below a lower threshold or above an upper threshold, respectively. The system's controller may repeat the transferring, calculating, and adjusting processes for multiple wafers and determine a trend in settling time adjustments over time, enabling long-term process optimization. The system may utilize an AWC sensor array comprising at least two sensors positioned on opposite sides of one or more gate valves, allowing for precise wafer position detection during transfer operations. The controller may store the calculated position difference in the memory and use this stored data to adjust subsequent wafer handling operations, enhancing the system's adaptive capabilities over time. In the system, the controller may calculate the wafer position during place or pick operations by detecting the wafer edge using the AWC sensor array and determining the offset of the wafer center from a predetermined position on the end effector. The adjustment of the settling window in the system may include adjusting the velocity profile of the end effector, allowing for precise control of wafer movement.

In accordance with examples of the disclosure, a method is provided that may involve receiving a wafer settling window for a wafer processing system and cyclically performing operations for picking and placing wafers carried by an end effector of a wafer transfer robot within the substrate processing system using the wafer settling window. The method also may include determining the accuracy of two or more of the cyclic picking and placing operations in the substrate processing system using an automatic wafer centering sensor arranged along a movement path of the end effector. This method may further comprise calculating a position difference between a wafer position during a pick operation and a wafer position during a place operation, and adjusting the wafer settling window based on the calculated position difference. The determination of accuracy in the cyclic picking and placing operations may involve detecting the edge of the wafer using the automatic wafer centering sensor during pick and place operations and calculating an offset of the wafer center from a predetermined position on the end effector for each operation. The method also may include storing the determined accuracy of the cyclic picking and placing operations in a memory, analyzing the stored accuracy data to identify trends over time, and predicting maintenance needs for the wafer transfer robot based on the identified trends.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1A schematically illustrates a wafer processing system with dual chamber modules usable in accordance with one or more embodiments of the disclosure;

FIG. 1B schematically illustrates a wafer processing system with single chamber modules usable in accordance with some examples of this technology;

FIG. 2 schematically illustrates the passing of a wafer through a gate value in accordance with one or more embodiments of the disclosure;

FIG. 3 provides a flow chart generally describing features of methods in accordance with one or more embodiments of the disclosure;

FIG. 4 provides a flow chart describing features of methods in accordance with one or more embodiments of the disclosure;

FIG. 5 schematically illustrates a computer processing system for controlling a wafer processing system in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

Material layers (e.g., films) are commonly deposited onto wafers during the fabrication of semiconductor devices, such as during the fabrication of integrated circuits and electronic devices. The terms “wafer” and “substrate” may refer to any underlying material or materials that may be used or upon which a device, a circuit, or a film may be formed, which is typically a semiconductor wafer. The terms “film” and “thin film” may refer to any continuous or non-continuous structures and material deposited by the methods disclosed herein. For example, “film” and “thin film” could include 2D materials, nanorods, nanotubes, or nanoparticles, or even partial or full molecular layers or partial or full atomic layers or clusters of atoms and/or molecules. “Film” and “thin film” may comprise a material or a layer with pinholes but still be at least partially continuous.

Substrate processing systems employ wafer-handling robots to transfer wafers between various chambers and components. These robots utilize end effectors to grasp and move wafers with precision. When a wafer-handling robot changes the location, direction, or velocity of its end effector, it requires a certain amount of time to settle into the desired position and velocity. For instance, as a robot arm moves a wafer through a gate valve into a chamber and places it on a wafer support, the end effector decelerates to come to rest at the final position. However, depending on factors such as the robot arm's velocity, acceleration, inertia, stiffness, and actuator force, the position of the end effector may oscillate or vibrate before finally settling.

To manage this settling process, a predetermined settling window may be defined. This settling window encompasses parameters such as position tolerance, velocity tolerance, and settling time. The position tolerance specifies an acceptable range around the final position, while the velocity tolerance defines an acceptable range around the final velocity (often zero velocity). The settling time represents the duration within which the end effector must remain within these position and velocity tolerances. These parameters collectively indicate the completion of a motion or change in motion for the wafer-handling robot.

The predefined settling window may be used to determine the positional accuracy of wafer placement by the wafer-handling robot. Moreover, it affects the repeatability of the robot's performance when executing the same motion repeatedly, such as moving wafers sequentially in and out of a chamber. The configuration of the settling window presents a trade-off between accuracy and processing speed. A narrow settling window, characterized by smaller position and velocity tolerances and/or longer settling times, may result in improved positional accuracy. However, this increased precision may come at the cost of longer pick and place operation times for the wafer-handling robot, potentially reducing overall throughput.

Conversely, a wider settling window, featuring larger position and velocity tolerances and/or shorter settling times, may lead to faster pick and place operations. This approach may enhance the overall processing speed of the semiconductor system. However, the trade-off is a potential increase in positional errors when placing wafers on the wafer support within the chamber. Such errors can impact the uniformity and quality of subsequent processing steps, potentially affecting the yield and performance of the manufactured semiconductor devices.

Aspects described herein relate to a system and method that utilizes AWC sensor data to calculate the effectiveness of settling windows. Based on AWC sensor readings during pick operations related to corresponding prior place operations for a specified positional accuracy, the settling window is automatically adjusted to reduce robot move times, potentially increasing throughput. As the wafer processing system is used repeatedly, wear in components like robot arm mountings, linkages, actuators, and end effector surfaces may alter the wafer-handling robot's performance, potentially changing oscillations and vibrations of the end effector induced by accelerating and decelerating the robot arm over time. Aspects include automatically adjusting the settling window based on these changes. This enables the wafer-handling robot to actively control the accuracy of the settling window based on user-defined wafer placement accuracy settings.

The system and method read AWC readings when placing a wafer in a chamber and picking a wafer from a chamber to determine offset, then adjusts the settling window based on that offset. This approach allows tracking and comparison to baseline settings over time, enabling the system to learn and adjust by opening up the settling window as needed while maintaining required parameters. The system may eventually reach a point where it can no longer maintain the needed positional accuracy or pick and place capability.

This approach can contribute to diagnostics and health monitoring of the robot. By addressing variation in settling time initially, subsequent setup and placement may become more accurate. Aspects aim to optimize the balance between positional accuracy and throughput in wafer handling operations.

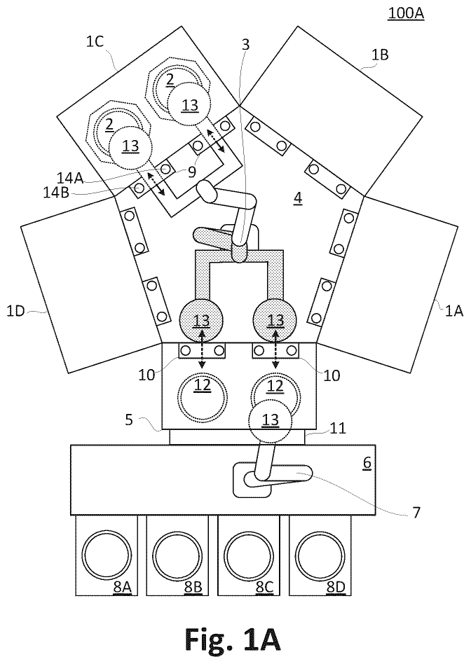

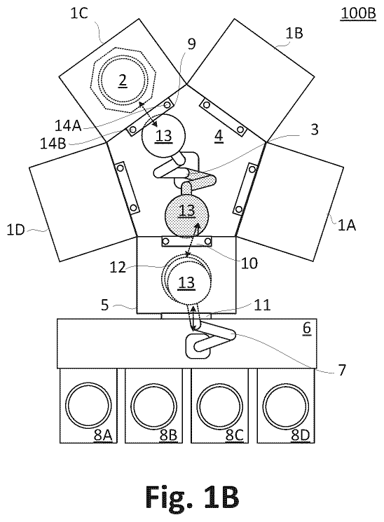

Turning now to the figures, FIG. 1A schematically illustrates a top view of a “cluster type” wafer processing system 100A in accordance with some examples of this technology. The wafer processing system 100A may include a wafer handling chamber 4 that connects with four wafer processing chambers 1A-1D via gate valves 9. The system 100A also comprises a load-lock module 5, an equipment front-end module 6, and multiple load ports 8A-8D. The wafer handling chamber 4 houses a wafer handling robot 3 used to transfer wafers 13 between the various chambers and modules.

The wafer processing chambers 1A-1D are arranged around the wafer handling chamber 4. Each wafer processing chamber 1A-1D may include two wafer supports 2, onto which wafers 13 can be placed during processing. The wafer supports 2 are designed to hold the wafers 13 securely during various processing steps, such as material layer deposition. The chambers 1A-1D may have identical structures, or one or more chambers may have different structures to accommodate various processing requirements.

System 100A includes a wafer handling robot within wafer handling chamber 4. This robot may include two robotic arms, each equipped with end effectors (not shown) for supporting and transporting wafers 13. One robotic arm (unshaded) is illustrated moving two wafers 13 in wafer processing chamber 1C, while the other robotic arm (shaded) is shown moving two wafers 13 from the load-lock module 5. The dual-arm configuration allows for efficient and simultaneous wafer transfers, potentially increasing overall system throughput.

Gate valves 9 are positioned between the wafer handling chamber 4 and each of the wafer processing chambers 1A-1D. These gate valves 9 serve as sealable interfaces, allowing the robotic arms to extend through when open to insert or remove wafers from the processing chambers. When closed, the gate valves 9 isolate the environments of the wafer processing chambers from the wafer handling chamber, maintaining the specific conditions required for wafer processing.

The load-lock module 5 acts as an intermediary chamber between the wafer handling chamber 4 and the external environment. It connects to the wafer handling chamber 4 via one or more gate valves 10. The interior of the load-lock module 5 contains wafer holding components 12 for temporarily storing wafers as they enter or exit the wafer handling chamber 4. This module allows for the controlled transfer of wafers between the atmospheric pressure environment outside and the controlled environment inside the wafer handling chamber.

The equipment front-end module 6 is coupled to the load-lock module 5 via one or more gate valves 11. This module houses a front-end robot 7 with one or more robotic arms. The front-end robot 7 is responsible for transferring wafers between the load ports 8A-8D and the load-lock module 5. The load ports 8A-8D serve as interfaces for loading new wafers into the system and unloading processed wafers from the system.

AWC sensors 14A and 14B are positioned near each gate valve 9 between the wafer processing chambers and the wafer handling chamber 4. These sensors play a role in determining the position, velocity, and/or acceleration of wafers as they are transported by the robotic arms. The AWC sensors can detect any eccentricity of the wafer relative to a predetermined location on the end effector, ensuring precise wafer placement and reducing the risk of misalignment during processing.

In some examples, the wafer processing system may include additional wafer supports horizontally offset from the wafer supports 2 (e.g., 4 total wafer supports) shown in FIG. 1A. In other examples, the wafer processing system may include additional wafer supports vertically stacked beneath the wafer supports 2 shown in FIG. 1A. This configuration could potentially increase the processing capacity of each chamber without significantly expanding the system's footprint. Furthermore, the number of robotic arms on the wafer handling robot 3 could be increased or decreased based on specific throughput requirements and system design considerations.

FIG. 1B schematically illustrates a top view of another “cluster type” wafer processing system 100B in accordance with some examples of this technology. System 100B may include similar components to those in system 100A and identified with the same numbers. For example, the wafer processing system 100B may include a wafer handling chamber 4 that operatively connects with one to four wafer processing chambers 1A-1D via gate valves 9. Each wafer processing chamber 1A-1D may include one wafer support 2 onto which a wafer 13 can be placed during processing. The system 100B also comprises a load-lock module 5, an equipment front-end module 6, and multiple load ports 8A-8D.

The wafer handling chamber 4 serves as the central hub of the wafer processing system 100B. It houses a wafer handling robot 3, also referred to as a back-end robot, which is used to move wafers 13 into and out of the various wafer processing chambers 1A-1D through the gate valves 9. The wafer handling robot 3 in system 100B may include two robotic arms, each equipped with a single end effector upon which a single wafer 13 is supported. This configuration allows for efficient and precise movement of wafers between different chambers.

Each wafer processing chamber 1A-1D is designed to perform specific processing steps on the wafers. While the internal details are not shown for all chambers in FIG. 1B, it can be inferred that each chamber is equipped to receive a wafer 13 on the wafer support 2 and hold the wafer during processing. The processing may include various steps such as material layer deposition, etching, or other semiconductor fabrication processes. The single wafer support 2 in each chamber allows for individual wafer processing, which can be advantageous for certain manufacturing processes.

The gate valves 9 are positioned between the wafer handling chamber 4 and each of the wafer processing chambers 1A-1D. These gate valves 9 can be opened to allow the robotic arm of the wafer handling robot 3 to extend through and insert or remove a wafer from a wafer processing chamber. When closed, the gate valves 9 seal the wafer processing chambers from the wafer handling chamber 4, maintaining the specific environmental conditions required for wafer processing.

The system 100B is equipped with AWC sensors, specifically a pair of AWC sensors 14A and 14B, disposed near each gate valve 9 between each chamber and the wafer handling chamber 4. These AWC sensors are utilized to determine various parameters of the wafer as it is carried and moved by the robotic arms. For instance, as in system 100A, they can measure the position, velocity, or acceleration of a wafer, as well as determine the eccentricity of the wafer relative to a predetermined location on the end effector.

The load-lock module 5 serves as an intermediary chamber between the wafer handling chamber 4 and the external environment. It is connected to the wafer handling chamber 4 via one or more gate valves 10. The load-lock module 5 contains wafer holding components 12 for holding wafers in transit. This module allows for the controlled introduction and removal of wafers from the system without compromising the controlled environment of the wafer handling chamber 4.

The equipment front-end module 6 is coupled with the load-lock module 5 via one or more additional gate valves 11. This module houses a front-end robot 7 with one or more robotic arms. The front-end robot 7 is responsible for moving wafers between the equipment front-end module 6 and the load-lock module 5, as well as picking up new wafers for processing from the load ports 8A-8D and returning processed wafers to these ports.

The load ports 8A-8D, represented as circular components in FIG. 1B, are the interface points where wafers enter and exit the wafer processing system 100B. These ports may be designed to accommodate standard wafer carriers or front opening unified pods (FOUPs) used in semiconductor manufacturing. The multiple load ports allow for continuous operation, with new wafers being loaded while processed wafers are unloaded.

In operation, the wafer processing systems 100A and 100B each function as an integrated unit to process semiconductor wafers. New wafers are introduced through the load ports 8A-8D, transferred by the front-end robot 7 to the load-lock module 5, and then moved by the wafer handling robot 3 to the various wafer processing chambers 1A-1D as needed. The AWC sensors 14A and 14bB ensure precise positioning of the wafers throughout this process. After processing, the wafers follow the reverse path to exit the system. This configuration allows for efficient, high-volume wafer processing while maintaining the necessary controlled environments for semiconductor fabrication.

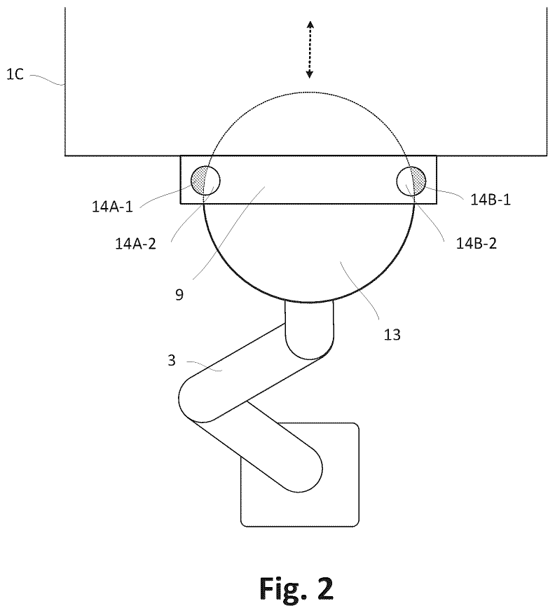

FIG. 2 illustrates a detailed view of a wafer processing chamber 1C, which is a component of the wafer transfer system described in FIGS. 1A and 1B. The wafer processing chamber 1C may include a wafer support 2 (not illustrated) for holding a wafer 13 during processing. The chamber 1C is connected to the wafer handling chamber 4 via a gate valve 9, allowing the wafer handling robot 3 to transfer wafers in and out of the chamber. Auto wafer centering (AWC) sensors 14A and 14B are positioned near the gate valve 9 to determine the position, velocity, and acceleration of wafers as they are moved by the robotic arms.

The wafer support 2 within the wafer processing chamber 1C is designed to securely hold the wafer 13 during various processing operations. The support may be equipped with mechanisms to adjust its height, rotate the wafer, or provide thermal control. In alternative examples, the wafer support 2 could incorporate electrostatic clamping technology to enhance wafer stability during high-temperature processes. Additionally, the support may feature integrated heating or cooling elements to precisely control the wafer temperature during processing.

The gate valve 9 serves as an interface between the wafer processing chamber 1C and the wafer handling chamber 4. When opened, it allows the robotic arm of the wafer handling robot 3 to extend through and transfer wafers. The gate valve 9 is designed to maintain a seal when closed, preserving the controlled environment within the processing chamber. In some aspects, the gate valve 9 may incorporate a double-door design for enhanced isolation, or utilize specialized materials for improved vacuum integrity and reduced particle generation.

The wafer 13 shown entering or existing the chamber represents a pick or place operation, respectively. Wafers can vary in size and material composition depending on the specific application. While silicon wafers are commonly used, alternative aspects may process wafers made from other semiconductor materials such as gallium arsenide, silicon carbide, or germanium. The system can handle different wafer sizes, from small research-scale wafers to large production-scale wafers up to 300 mm or 450 mm in diameter.

The wafer handling robot 3 is used to transfer wafers to and from the processing chamber 1C. The robot's end effector, which directly contacts the wafer on the bottom side of the wafer (not shown), is designed for precision and cleanliness. It may utilize vacuum suction, edge gripping, or Bernoulli-effect lifting to securely hold the wafer during transfer. Some examples of the robot may incorporate multiple degrees of freedom for complex movements or dual-arm configurations for increased throughput.

The AWC sensors 14A and 14B positioned near the gate valve 9 ensure accurate wafer placement and movement. These sensors typically use optical or capacitive sensing technologies to detect the wafer's position with high precision. For example, as the wafer passes across a field of view of each sensor, a portion of the field of view of each sensor may be obscured (e.g., unshaded portion 14A-2, 14B-2), while another portion may be unobscured (e.g., shaded portion 14A-1, 14A-2). The data from these sensors (e.g., indicating which portions of the field of view are obscured or unobscured) may be used to calculate any eccentricity or misalignment of the wafer relative to the robot's end effector. This information allows the system to make real-time adjustments to the robot's movements, ensuring optimal wafer placement within the chamber. In alternative aspects, additional sensors may be incorporated to provide redundancy or to capture more detailed information about the wafer's orientation and condition.

The wafer processing chamber 1C is designed to accommodate various processing operations, such as deposition, etching, or annealing. While specific processing equipment is not shown in this figure, the chamber would typically include gas inlets, exhaust ports, and other components for the intended processes. The chamber walls may be constructed of materials chosen for their compatibility with specific process chemistries and temperatures. In some aspects, the chamber may feature viewports or integrated metrology capabilities for in-situ process monitoring.

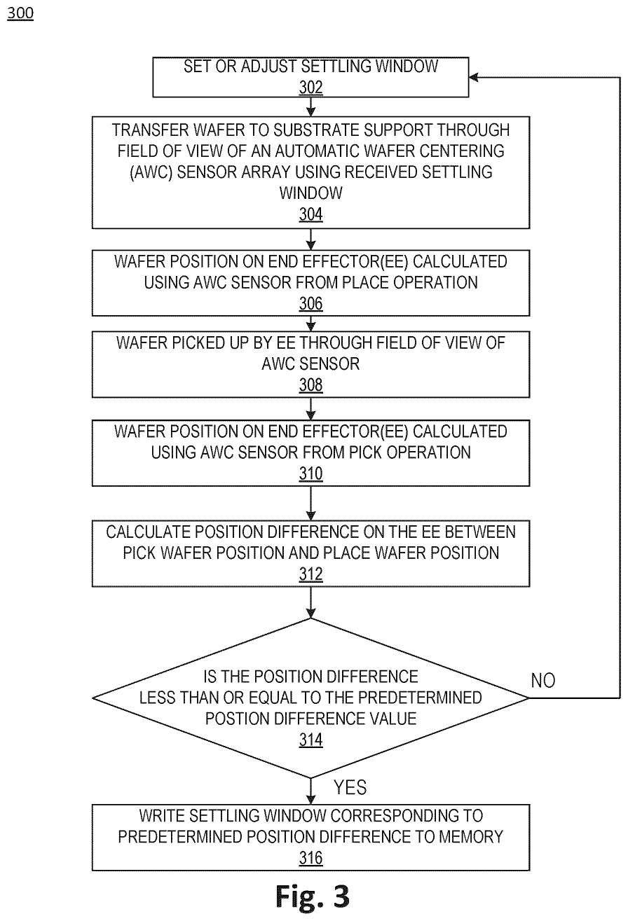

FIG. 3 illustrates a flowchart depicting a process 300 for wafer settling window adjustment in a wafer processing system. The flowchart outlines a series of steps for optimizing the settling window of wafers during transfer operations, utilizing AWC sensor data to improve accuracy and throughput. The process may involve setting an initial settling window, transferring wafers, calculating wafer positions, and adjusting the settling window based on position differences.

The process begins at step 302 by setting an initial settling window for the wafer transfer operations. This initial settling window is a predetermined value that allows for the wafer to stabilize after movement. The settling window is for ensuring accurate placement and minimizing vibrations that could affect subsequent processing steps. The initial settling window may be set, for example, during initial installation and calibration of the system.

The next step 304 may involve transferring a wafer to a substrate support through the field of view of an AWC sensor array. This transfer is performed using the initially set settling window. The AWC sensor array is a component that provides precise measurements of the wafer's position during transfer operations. It utilizes advanced sensing technologies such as optical or capacitive sensors to detect the wafer's edges and center.

Following the transfer, the wafer position on the end effector (EE) is calculated in step 306 (e.g., by a controller or processor of the wafer processing system) using data from the AWC sensor during the place operation. This calculation provides a reference point for the wafer's position after it has been placed on the substrate support. The end effector is the part of the robotic arm that directly contacts and holds the wafer during transfer operations.

The process then moves to step 308 which includes transferring a wafer during a pick-up operation, where the wafer is picked up by the end effector and again passes through the field of view of the AWC sensor. This step allows for a second measurement of the wafer's position, this time during the pick operation. The AWC sensor data is used in step 310 to calculate the wafer position on the end effector during this pick operation.

Step 312 includes calculating (e.g., by a controller or processor of the wafer processing system) the position difference on the end effector between the pick wafer (e.g., first) position and the place (e.g., second) wafer position. This difference represents any discrepancies in wafer placement and pickup, which could be caused by various factors such as vibrations, mechanical wear, or inconsistencies in the robotic arm's movement.

In step 314, the calculated position difference is then compared (e.g., by a controller or processor of the wafer processing system) to a predetermined position difference value. This comparison serves as a decision point in the process. If the position difference is less than or equal to the predetermined value, it indicates that the current settling window is sufficient for accurate wafer placement and pickup.

If the position difference meets the predetermined criteria, the process proceeds to step 316 to store the current settling window corresponding to the predetermined position difference to the system memory (e.g., by a controller or processor of the wafer processing system writing the settling window parameters to memory). This step updates the settling window parameter used in future wafer transfer operations, potentially optimizing the process for improved throughput.

In cases where the position difference exceeds the predetermined value, the process may return to step 302 to adjust the settling window, which may include additional steps (not shown in the flowchart). This could involve incrementally increasing the settling window and repeating the transfer process until the desired accuracy is achieved.

The process described in FIG. 3 represents an iterative approach to optimizing wafer handling in semiconductor manufacturing. By continuously monitoring and adjusting the settling window based on real-time AWC sensor data, the system can maintain high accuracy in wafer placement while minimizing unnecessary delays. This adaptive process contributes to improved overall efficiency and yield in wafer processing operations.

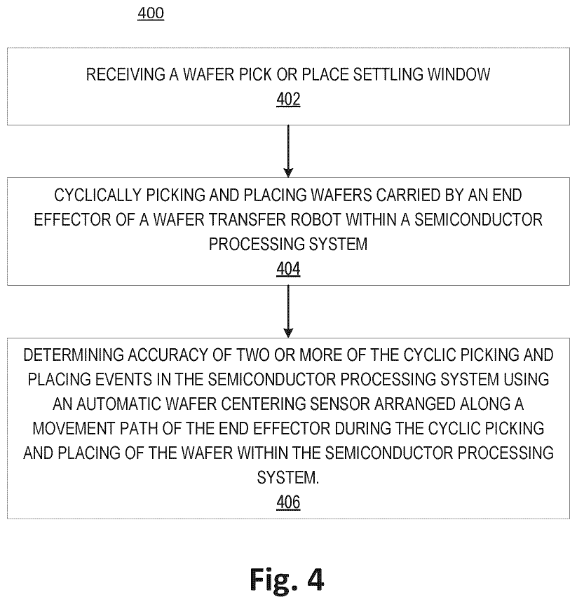

FIG. 4 illustrates a high-level flowchart of wafer processing and accuracy determination in a substrate processing system. The flowchart depicts a method for optimizing wafer handling operations by dynamically adjusting settling windows based on AWC sensor data.

The method begins in step 402 by receiving a wafer pick or place settling window (e.g., by a controller or processor of the wafer processing system retrieving settling window parameters from memory or from a user interface). This settling window may include the duration allowed for vibrations and oscillations to subside after a wafer transfer robot moves a wafer. The initial settling window may be predetermined based on system specifications or historical data.

The next step 404 may involve performing cyclic operations of picking and placing wafers carried by an end effector of a wafer transfer robot within the substrate processing system. This cyclic operation is a process in wafer handling, where wafers are repeatedly moved between various chambers or stations for different processing steps. The end effector may include a specialized gripper or paddle at the end of the robot arm, which securely holds the wafer during these transfer operations.

Following the cyclic picking and placing of wafers, the method proceeds to step 406 for determining accuracy of two or more of these cyclic picking and placing events. This determination is made using an automatic wafer centering sensor arranged along the movement path of the end effector during the cyclic picking and placing of the wafer within the substrate processing system. The AWC sensor provides precise measurements of wafer position and orientation, allowing the system to assess the accuracy of each pick and place operation. Accuracy data indicating the determined accuracy may be stored to memory and used for subsequent operations.

The AWC sensor data is used for evaluating the effectiveness of the current settling window. By analyzing the positional accuracy of the wafers after one or more pick and place cycles, the system can determine if the current settling window is sufficient or if adjustments are needed. This analysis may take into account factors such as the desired positional accuracy, which may be user-defined or determined by the system based on process requirements.

Based on the accuracy determination, the method may involve automatically adjusting the settling window. If the AWC sensor data indicates that wafers are consistently placed with high accuracy, the settling window might be reduced to improve throughput. Conversely, if the data shows positioning errors, the settling window may be increased to ensure proper wafer placement.

The flowchart represents an iterative process, where the system continuously monitors and optimizes the settling window based on real-time performance data. This adaptive approach allows the substrate processing system to maintain high accuracy while maximizing efficiency, even as system components experience wear over time.

By implementing this method, the substrate processing system can actively control the accuracy of wafer placement while minimizing robot move times. This optimization leads to increased throughput and improved overall system performance, addressing the critical balance between speed and precision in wafer handling operations.

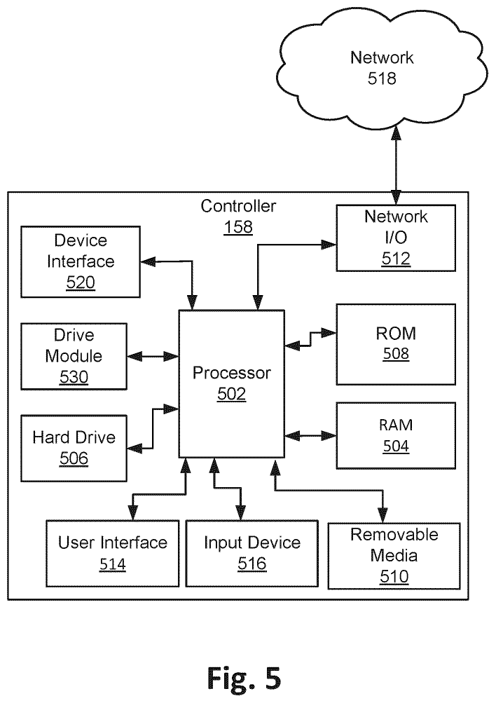

FIG. 5 shows a block diagram of a controller 500 for implementing the wafer transfer process in wafer processing systems such as 100A and 100B. The controller 500 may include various interconnected components that work together that are configured to control and manage the wafer handling operations in a substrate processing system.

The controller 500 comprises one or more processors 502 which execute instructions to carry out the wafer transfer operations, such as those in processes 300 and 400. These processors 502 may be general-purpose microprocessors or specialized processors optimized for control applications. The processors 502 are connected to and can access various memory components including random access memory (RAM) 504, read-only memory (ROM) 508, and a hard drive 506. The RAM 504 provides temporary storage for data and instructions being processed by the processors 502. The ROM 508 stores firmware and other non-volatile data needed for system operation. The hard drive 506 provides larger capacity storage for programs, configuration data, and logged information related to wafer transfer operations.

A removable media interface 510 allows the controller 500 to read data and programs from removable storage devices like universal serial bus (USB) drives, memory cards, or optical discs. This provides a convenient way to update software or load new configuration data into the controller. The removable media 510 can also be used to transfer logged data or diagnostic information from the controller to other systems for analysis.

The controller 500 may include a network interface 512 that enables communication with other systems on a network 518. This allows the controller to receive commands from and report status to a central control system. It can also enable remote monitoring and troubleshooting of the wafer handling system. The network interface 512 may support wired Ethernet connections or wireless protocols like Wi-Fi.

A user interface 514 provides a way for operators to directly interact with and control the system. This may include a display screen to show system status and menus, along with input devices 516 like buttons or a touchscreen. The user interface 514 allows manual control and configuration of the wafer handling operations when needed. Multiple user interface options could be provided, such as a full graphical interface on the main controller and simplified interfaces on remote terminals.

The controller 500 may include a device interface 520 for connecting to and controlling the various components of the wafer handling system. This interface allows the controller to actuate robot arms, open and close valves, read sensor data, and control other electromechanical elements involved in wafer transfer. The device interface 520 may use standardized protocols like Modbus or custom interfaces optimized for real-time control.

A drive module 530 within the controller 500 provides specialized functionality for controlling the motion of wafer handling robots and other moving components. This module may include motion planning algorithms, trajectory generation, and closed-loop control systems to ensure precise and smooth movement of wafers. The drive module 530 works in conjunction with the processors 502 to coordinate complex multi-axis motions.

The various components of the controller 500 work together to implement the wafer transfer process. The processors 502 execute the main control logic, using sensor data and predefined recipes to determine when and how to move wafers. The drive module 530 translates high-level move commands into detailed motion profiles. The device interface 520 sends the resulting control signals to the physical hardware. Simultaneously, status information flows back through the device interface 520 to the processors 502 for monitoring and adaptive control.

The controller 500 implements a closed-loop control system, continuously adjusting its outputs based on feedback from sensors in the wafer handling system. This allows it to compensate for variations in wafer position, robot arm dynamics, and other factors that could impact transfer accuracy. The controller can also implement more advanced control schemes like model predictive control or adaptive control to optimize performance over time.

In addition to basic wafer transfer operations, the controller 500 can implement higher-level functions like scheduling, load balancing between multiple process chambers, and coordinating with other subsystems in the semiconductor fabrication line. The network interface 512 allows it to receive overall production plans and report detailed status information back to a manufacturing execution system.

The controller 500 also implements various safety and error handling functions. It monitors for anomalous conditions like misplaced wafers or robot malfunctions, taking appropriate action to prevent damage or contamination. This may include stopping operations, retracting robots to safe positions, or alerting operators through the user interface 514 or network connections.

Data logging and analysis capabilities are also provided by the controller 500. It can record detailed information about each wafer transfer operation, including timing, positions, and any errors encountered. This data can be stored on the hard drive 506 or removable media 510 for later analysis to identify trends, optimize performance, or troubleshoot issues.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

1. A method for adjusting a settling window in a substrate processing system, comprising:
transferring, during a place operation, a wafer through a field of view of an automatic wafer centering sensor array using a current settling window;
calculating a first wafer position on an end effector during the place operation using the automatic wafer centering sensor array;
transferring, during a pick operation, the wafer through the field of view of the automatic wafer centering sensor array using the current settling window;
calculating a second wafer position on the end effector during the pick operation using the automatic wafer centering sensor array;
calculating a position difference between the first wafer position and the second wafer position; and
adjusting the current settling window based on the position difference.

2. The method of claim 1, further comprising:
comparing the position difference to a predetermined position difference value;
determining the position difference is less than or equal to the predetermined position difference value; and
writing a new settling window to system memory based on the position difference being less than or equal to the predetermined position difference value.

3. The method of claim 1, wherein adjusting the settling window comprises:
decreasing a settling time in response to the position difference being less than a lower threshold; or
increasing the settling time in response to the position difference being greater than an upper threshold.

4. The method of claim 1, further comprising:
repeating, for multiple wafers: the transferring during the place operation, the calculating during the place operation, the transferring during the pick operation, the calculating during the pick operation, the calculating the position difference, and the adjusting; and
determining a trend in settling time adjustments over time.

5. The method of claim 1, wherein the automatic wafer centering sensor array comprises at least two sensors positioned on opposite sides of a gate valve.

6. The method of claim 1, further comprising:
storing the position difference in a memory; and
using the position difference stored in the memory to adjust subsequent wafer handling operations.

7. The method of claim 1, wherein calculating the first wafer position or the second wafer position comprises:
detecting an edge of the wafer using the automatic wafer centering sensor array; and
determining an offset of a wafer center from a predetermined position on the end effector.

8. The method of claim 1, wherein the adjusting of the settling window comprises adjusting a velocity profile of the end effector.

9. A substrate processing system, comprising:
a wafer transfer robot with an end effector,
an automatic wafer centering sensor array,
a processing chamber with a substrate support, and
a controller configured to:
control the wafer transfer robot to transfer a wafer during a place operation through a field of view of the automatic wafer centering sensor array using a current settling window;
calculate a first wafer position on the end effector during the place operation using the automatic wafer centering sensor array;
control the wafer transfer robot to transfer a wafer during a pick operation through the field of view of the automatic wafer centering sensor array using the current settling window;
calculate a second wafer position on the end effector during the pick operation using the automatic wafer centering sensor array;
calculate a position difference between the first wafer position and the second wafer position; and
adjust the current settling window based on the position difference.

10. The substrate processing system of claim 9, further comprising a memory coupled to the controller, wherein the controller is configured to:
compare the position difference to a predetermined position difference value;
determine the position difference is less than or equal to the predetermined position difference value; and
write a new settling window to the memory based on the position difference being less than or equal to the predetermined position difference value.

11. The substrate processing system of claim 9, wherein the controller is configured to adjust the current settling window by:
decreasing a settling time in response to the position difference being less than a lower threshold; or
increasing the settling time in response to the position difference being greater than an upper threshold.

12. The substrate processing system of claim 9, wherein the controller is further configured to:
repeat, for multiple wafers: the transferring during the place operation, the calculating during the place operation, the transferring during the pick operation, the calculating during the pick operation, the calculating the position difference, and the adjusting; and
determine a trend in settling time adjustments over time.

13. The substrate processing system of claim 9, wherein the automatic wafer centering sensor array comprises at least two sensors positioned on opposite sides of a gate valve.

14. The substrate processing system of claim 9, further comprising:
a memory coupled to the controller, wherein the controller is configured to:
store the position difference in the memory; and
use the position difference stored in the memory to adjust subsequent wafer handling operations.

15. The substrate processing system of claim 9, wherein the controller is configured to calculate the first wafer position or the second wafer position by:
detecting an edge of the wafer using the automatic wafer centering sensor array; and
determining an offset of a wafer center from a predetermined position on the end effector.

16. The substrate processing system of claim 9, wherein the adjusting of the current settling window comprises adjusting a velocity profile of the end effector.

17. A method, comprising:
receiving a wafer settling window for a substrate processing system;
performing cyclic operations of picking and placing wafers carried by an end effector of a wafer transfer robot within the substrate processing system using the wafer settling window; and
determining accuracy of two or more of the cyclic operations using an automatic wafer centering sensor arranged along a movement path of the end effector.

18. The method of claim 17, further comprising:
calculating, for one of the cyclic operations, a position difference between a first wafer position during a pick operation and a second wafer position during a place operation; and
adjusting the wafer settling window based on the position difference.

19. The method of claim 17, wherein the determining of the accuracy comprises:
detecting an edge of the wafers using the automatic wafer centering sensor during the cyclic operations; and
calculating offsets of the wafers from a predetermined position on the end effector for each operation.

20. The method of claim 17, further comprising:
storing the accuracy as accuracy data in a memory;
analyzing the accuracy data stored in the memory to identify trends over time; and
predicting maintenance needs for the wafer transfer robot based on the trends.
